(19) United States
(12) Patent Application Publication
(10) Pub. No.: US 2012/0055105 A1
(43) Pub. Date: Mar. 8, 2012

(54) ADHESIVES AND SEALANTS BASED ON SILANE-TERMINATED BINDERS FOR BONDING AND SEALING FLEXIBLE SOLAR FILMS/PHOTOVOLTAIC MODULES

(75) Inventors: Matthias Kohl, Weinheim (DE); Manfred Proebster, Nubloch (DE); Thilo Fertig, Bruhl (DE)

(73) Assignee: Henkel AG & Co. KGaA, Duesseldorf (DE)

(21) Appl. No.: 13/293,329

(22) Filed: Nov. 10, 2011

Related U.S. Application Data
(63) Continuation of application No. PCT/EP2010/057380, filed on May 28, 2010.

(30) Foreign Application Priority Data
Jun. 3, 2009 (DE) 10 2009 026 679.8

(51) Int. Cl. E04D 13/18; H01L 31/048; C09J 183/14

(52) U.S. Cl. 52/173.3; 156/329; 156/71; 136/251

(57) ABSTRACT

A single- or multi-component adhesive/sealant compositions containing at least one silane-terminated prepolymer, wherein the adhesive/sealant compositions are free of organic heavy metal catalysts, and the silane-terminated prepolymers comprise terminal groups that are selected from among methyldialkoxysilylpropyl, trialkoxysilylpropyl, methyldialkoxysilylmethyl, trialkoxysilylmethyl, or mixtures thereof. In the two-component embodiment, the adhesive/sealant compositions consist of a component A, containing at least one silane-terminated prepolymer of the aforementioned type, and a component B, containing water and thickener. Said adhesive/sealant compositions are used to elastically bond two or more identical and/or dissimilar substrates, in particular in the production of photovoltaic modules, and in the mounting of photovoltaic modules onto roof surfaces and other surfaces.

The present invention relates to a single- or multi-component adhesive/sealant based on silane-terminated prepolymers, to the use thereof for elastic adhesive bonding of two or more identical and/or dissimilar substrates and for primerless connecting of two or more identical and/or different substrates.

In the metal-processing industry, the vehicle industry, in commercial vehicle construction and in their supplier industries, in auto repair and in construction and the skilled trades, identical or different metallic and/or nonmetallic substrates are adhesively resp. sealingly connected to one another in many ways. A number of single-component resp. two- or multi-component adhesives/sealants are already available for this purpose. Single-component adhesives/sealants are generally preferred by users because no mixing and dispensing errors can occur in the context of their use, but the use of single-component moisture-curing adhesives/sealants for the adhesive bonding of non-porous substrates is greatly limited because of the relatively slow final hardening rate.

Conventional two-component adhesive/sealant systems contain in the one component binders having one type of reactive, crosslinking-capable groups, and in the second component binding-agent portions or hardeners whose functional groups are co-reactive with the reactive groups of the first component. Examples thereof are polyurethane systems having isocyanate-group-containing compounds in the one component, and binders or hardeners containing amino groups resp. hydroxyl groups or mercaptan groups in the second component. In the same fashion, the traditional two-component epoxy resin systems are made up of one component having binders that contain epoxy groups, and the associated second component comprises compounds having mercaptan groups resp. amino groups. It is disadvantageous in the context of such systems that these systems react very sensitively to mixing errors, since the two components attain their optimum hardening and properties only when they are completely mixed with one another at a stoichiometrically correct ratio.

EP 0678544 A1 describes two-component adhesive, sealing, or coating compounds made of a component A and a component D. Component A is said to cure as soon as it comes into contact with water or with component D which contains the hardener for component A. According to the teaching of this document, component D is said to be either a component B that contains a constituent which cures with water or optionally also upon contact with component A, or alternatively component D is to be a mixture of a solid and a volatile constituent that produces the crosslinking of component A. It is indicated as an advantage of this two-component system that component D acts as a hardener for component A, but an excess thereof either itself cures, or leaves behind no permanent troublesome residues in the hardened compound.

Simpler systems contain moisture-crosslinking binders as component A, and water or substances that emit water, and optionally a catalyst, as component B. U.S. Pat. No. 6,025,445 A, for example, describes a two-component adhesive/sealant system in which component A contains as a principal constituent a saturated hydrocarbon polymer that comprises silicon-containing groups which have hydrolyzable groups bound to the silicon atom and are crosslinkable with the formation of siloxane groups. Component B contains a silanol condensation catalyst and water or a hydrated metal salt.

WO 96/35761 A1 describes two-component adhesives/sealants based on silane-terminated prepolymers, whose component A is a single-component moisture-curing adhesive/sealant having high initial strength, and whose component B is a crosslinker and/or accelerator for component A. In particularly preferred embodiments, component B is said to be made up of a pasty, stable mixture of plasticizers, water, thickening agents, and optionally further adjuvants.

EP 370463 A2, EP 370464 A2, and EP 370531 A2 describe two- or multi-component adhesive compositions whose one component contains a liquid organic elastomeric polymer having at least one silane-group-containing reactive group per molecule as well as a hardening agent for an epoxy resin, and whose second component contains an epoxy resin as well as optionally a hardening catalyst for the elastomeric silane-group-containing polymer. The di- or polyamines, carboxylic acid anhydrides, alcohols, and phenols usual in epoxide chemistry, and optionally typical catalysts for the epoxide reaction, such as tertiary amines, salts thereof, imidazoles, dicyandiamide, etc., are proposed as hardening agents for the epoxy component. Two-component systems of this kind have the specific disadvantages of all standard two-component systems: the hardening rate and the final properties of the cured adhesive depend to a very large extent on correctly maintaining the mixing ratio of the components, and on how completely mixing occurs.

WO 2005/108520 A1 discloses two-component adhesives/sealants made up of a component A that contains at least one silane-terminated prepolymer, at least one catalyst for silane crosslinking, and low-molecular-weight organofunctional silanes, and a component B that contains at least one silane-terminated prepolymer, water, and agents that release water or absorb water. The catalysts proposed are preferably organometallic compounds such as tin compounds or titanium compounds. These compositions are said to be suitable for mixing-tolerant applications, since the two components are to be mixed with one another in substantially identical volumetric quantities prior to use. According to the teaching of this document, adhesives/sealants of this kind are suitable for adhesive bonding or sealing of components made of optionally painted metals such as aluminum or steel, in particular stainless steel, of glass, wood, and/or plastics.

US 2007/0088137 A1 describes moisture-hardening adhesive compositions that are substantially free of volatile organic compounds. They are said to be resistant to combustion and to ensure a high level of peeling resistance. They are said to be suitable for ensuring immobilization of a rubber membrane onto a rigid flat roof. The compositions contain polymers having hydrolyzable silane terminal groups, a phenol resin, and a non-polymeric hydrolyzable silane compound, the weight ratio of polymer having hydrolyzable silane terminal groups to phenol resin being said to be greater than 2:1.

EP 2 009 063 A discloses a two- or multi-component sealing compound encompassing a) a first component A containing a silane-terminated prepolymer based on an organic polymer, and a silane acting as a crosslinker and/or adhesion promoter, and b) a second component B containing a silane-terminated prepolymer based on an organic polymer and water. The pH of component B is said to be in a range from 3 to 7. This document, too, proposes the use of organometallic compounds, such as compounds of tin, aluminum, bismuth, zirconium, lead, iron, or titanium, as catalysts.

With the increase in substrates requiring adhesive bonding, and with rising demands being placed on the bonds and sealed joints, silyl-terminated adhesive/sealant systems (e.g. “MS polymers,” α-silanes, SPUR, so-called hybrids) are being used increasingly often both in industrial applications and in the skilled trades, because of their broad adhesion spectrum.

In the photovoltaic industry as well, adhesives or sealants based on silyl-terminated prepolymers are also being used alongside plastic butyl sealants or high-temperature-hardening EVA adhesives. These prepolymers are preferably based almost exclusively on the so-called MS polymers (Kaneka Co.). The adhesives and sealants are used in that context both in photovoltaic module production and also for mounting the completed photovoltaic modules. One sub-group of photovoltaic (PV) modules that is becoming increasingly significant is the so-called power-generating solar films (e.g. Uni-Solar “triple-junction” technology), also called “flexible” PV modules. These are made up of the photoactive layers that are embedded into plastic films and/or metal foils.

One possibility for the general construction of a PV module using triple-junction technology will be described briefly:

The solar films contain, as photoactive layers, a blue-sensitive, a green-sensitive, and a red-sensitive thin-film silicon layer, which respectively preferentially absorb the blue, yellow-green, and red component of sunlight. These layers are deposited, in a roll-to-roll vacuum deposition process, onto a stainless steel substrate and embedded into polymer layers. Onto the blue-sensitive layer a transparent layer of a conductive oxide film, and lastly an ethylene-vinyl acetate (EVA) layer as well as ETFE fluoropolymer layer (e.g. TEFZEL® of DuPont), are applied. The stainless-steel layer is adjoined on the underside by an EVA layer and an optionally fiber-reinforced polymer film (called a “polymer rear film”).

As compared with conventional, glass-shielded PV modules, these solar films have a very low inherent weight and, because of their high flexibility, are also obtainable in rolls. Manufacturers of these solar films are, for example, the Uni-Solar, Flexcell, and Fuji companies, and others. These flexible solar films are used in turn by roofing suppliers (e.g. the Alwitra company, Renolit in Belgium, FLAG in Italy) to manufacture building-integrated photovoltaic (BIPV) systems.

The roofing suppliers equip their roof sealing rolls (e.g. for flat roofs), resp. panels for metal roofs, with the aforementioned flexible solar films. In this context, the flexible solar film is connected to the roof sealing roll resp. to the metal panel, partly or over its entire surface, with the aid of an adhesive/sealant. The panels or sealing rolls, equipped in this fashion with solar films, are then applied (usually mechanically) onto or atop the buildings, and ensure sealing of the building while “incidentally” producing electrical power.

The butyl sealants used in the photovoltaic industry have the disadvantage that they have little strength, and can thus result in failure especially at elevated temperature. The EVA adhesives and sealants require curing conditions of 60 minutes at 100 to 160° C. These long process times greatly decrease the productivity of the manufacturing process. The adhesives or sealants based on silyl-terminated prepolymers that have hitherto been used furnish elastic adhesive bonds with sufficient strength even at elevated temperature, but under long-term stress at temperatures of 80° C. and/or temperature and moisture stresses of 85° C. and 85% relative humidity, a delamination of the flexible solar film occurs, in particular the polymer rear film.

A demand therefore exists for single- or multi-component adhesives/sealants having improved properties under long-term stress, such as encountered in the photovoltaic industry.

The manner in which the present invention achieves this object may be gathered from the Claims. It involves substantially making available a single- or multi-component adhesive/sealant composition containing at least one silane-terminated prepolymer having specific terminal groups, which is free of organic heavy-metal catalysts.

The subject matter of the invention is therefore single- or multi-component adhesive/sealant compositions containing at least one silane-terminated prepolymer, the adhesive/sealant composition being free of organic heavy-metal catalysts, and the terminal groups of the silane-terminated prepolymer being selected from methyldialkoxysilylpropyl, trialkoxysilylpropyl, methyldialkoxysilylmethyl, trialkoxysilylmethyl, or mixtures thereof.

“Methyldialkoxysilylpropyl” terminal groups are understood according to the present invention as groups of the formula CH₃(RO)₂Si—CH₂—CH₂-CH₂—, “trialkoxysilylpropyl” terminal groups as groups of the formula (RO)₃Si—CH₂—CH₂—CH₂—, “methyldialkoxysilylmethyl” terminal groups as groups of the formula CH₃(RO)₂Si—CH₂—, and “trialkoxysilylmethyl” terminal groups as groups of the formula (RO)₃Si—CH₂—, R in the formulas denoting in each case an alkyl residue, by preference a C₁ to C₈ alkyl residue, particularly preferably methyl, ethyl, or n-propyl, and very particularly preferably methyl or ethyl.

“Heavy metals” for purposes of this invention are those metals having a density greater than 3.5 g*cm⁻³.

Adhesive/sealant compositions are understood according to the present invention to be “free of organic heavy-metal catalysts” if their heavy-metal content, based in each case on the total weight of the adhesive/sealant composition and calculated as metal, is equal to a maximum of 0.01 wt %, by preference a maximum of 0.001 wt %, particularly preferably a maximum of 0.0001 wt %, and very particularly preferably 0 wt %.

The terminal groups of the silane-terminated prepolymer are preferably selected from trialkoxysilylpropyl, methyldialkoxysilylmethyl, trialkoxysilylmethyl, or mixtures thereof. Particularly preferably, the single- or multi-component adhesive/sealant compositions contain exclusively those silane-terminated prepolymers whose terminal groups are selected from trialkoxysilylpropyl, methyldialkoxysilylmethyl, trialkoxysilylmethyl, or mixtures thereof.

A further subject of the invention relates to use of the single- or multi-component adhesive/sealant composition according to the present invention for elastic adhesive bonding of two or more identical and/or dissimilar substrates, in particular in the context of the production of photovoltaic modules and in the mounting of photovoltaic modules onto roof surfaces and other surfaces. The single- or multi-component adhesive/sealant compositions according to the present invention can in principle be used advantageously in the manufacture and mounting of photovoltaic modules of any kind, i.e. conventional rigid modules as well as flexible PV modules. Use in the context of the manufacture and mounting of flexible PV modules is preferred.

Possibilities as substrates to be adhesively bonded or sealed are, in this context, in particular components made of optionally painted metals such aluminum, steel, in particular stainless steel, galvanized steels, pretreated, in particular phosphated steels, copper, or brass, of glass, of plastic, in particular plastic rolls for roof applications such as, for example, Evalon® (high-molecular-weight polymer alloy of ethylene-vinyl acetate terpolymer (EVA) and polyvinyl chloride (PVC), Alwitra company), and/or of wood or wood materials.

Particularly preferably, the single- or multi-component adhesive/sealant compositions according to the present invention are used in the manufacture and mounting of flexible PV modules for elastic adhesive bonding and sealing of an EVA layer and polymer rear film, the EVA layer preferably being a layer of pure EVA or a high-molecular-weight polymer alloy of ethylene-vinyl acetate terpolymer (EVA) and polyvinyl chloride (PVC), and the polymer rear film being a layer of polyester, PVC, polychloroprene, a polyolefin, or polyethylene terephthalate (PET), preferably a layer of PET.

A further subject of the invention relates to use of the single- or multi-component adhesive/sealant compositions according to the present invention for primerless connecting of two or more identical and/or different substrates, optionally treated by the action of plasma, corona, or flame,
the adhesive/sealant composition of the aforesaid kind being applied onto at least one substrate, such that in the case of the two-component embodiment, components A and B are mixed immediately before application, and
the further substrate or substrates being joined onto the free adhesive/sealant surface.

Use of the single- or multi-component adhesive/sealant composition according to the present invention ensures that the composite thus manufactured can quickly be further processed and/or transported without further mechanical immobilization.

What is preferably used in this context is a two-component adhesive/sealant composition made up of component A and component B such that prior to application, component A is mixed with component B at a ratio from 1:1 to 200: 1 parts by weight.

In a preferred embodiment of the two-component adhesive/sealant composition according to the present invention, the latter is embodied with two components. It is by preference made up of a component A containing at least one silane-terminated prepolymer, and a component B containing water as well as at least one thickening agent.

The two-component adhesive/sealant composition according to the present invention contains at least one silane-terminated prepolymer whose terminal groups are selected from methyldialkoxysilylpropyl, trialkoxysilylpropyl, methyldialkoxysilylmethyl, trialkoxysilylmethyl, or mixtures thereof.

The terminal groups are therefore groups of the formula CH₃(RO)₂Si—CH₂—CH₂—CH₂—, groups of the formula (RO)₃Si—CH₂—CH₂—CH₂—, groups of the formula CH₃(RO)₂Si—CH₂—, and/or groups of the formula (RO)₃Si—CH₂—, R in the formulas denoting in each case an alkyl residue, by preference a C₁ to C₈ alkyl residue, particularly preferably methyl, ethyl, or n-propyl, and very particularly preferably methyl or ethyl.

Silane-terminated prepolymers that comprise at least one, by preference two or three, of the aforesaid reactive terminal groups are preferably used.

Particularly preferred are silane-terminated prepolymers of formula (1)

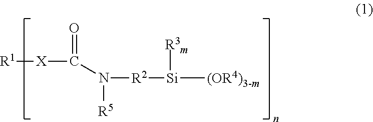

in which R¹ is the di-, tri-, or tetravalent residue of a polymer, in particular of a polymer having a polyoxyalkylene backbone, X is —O— or —NH, by preference —O—, R² is —(CH₂)— or —(CH₂)₃—, m is 0 or 1, and n is 2, 3, or 4. If R² denotes —(CH₂)₃—, m is by preference equal to 0. R³ denotes methyl. R⁴ is a C₁ to C₈ alkyl residue, particularly preferably a C₁ to C₄ alkyl residue, more preferably methyl, ethyl, or n-propyl, and very particularly preferably methyl or ethyl. R⁵ can be H or an alkyl, cycloalkyl, or aryl residue. R⁵ preferably denotes H.

Very particularly preferably, at least one silane-terminated prepolymer of the single-component composition, or of component A, is a silane-terminated polyoxyalkylene having N-(dimethoxy(methyl)silylmethyl)carbamate terminal groups, i.e. a prepolymer of formula (1) such that R¹ denotes a di-, tri-, or tetravalent residue of a polyoxyalkylene, X denotes —O—, R² denotes —(CH₂)—, m denotes 1, n denotes 2, 3, or 4, R³ denotes methyl, and R⁴ likewise denotes methyl. R⁵ can be H or an alkyl, cycloalkyl, or aryl residue. R⁵ preferably denotes H.

The silane-terminated prepolymers that are used have by preference a molecular weight (Mₙ) between 1000 and 50,000, particularly preferably 4000 to 20,000.

The silane-terminated prepolymers to be used according to the present invention can be manufactured in a manner known per se. For example, they can be obtained by reacting polyoxyalkylene polyols, in particular the di-, tri-, or tetravalent polypropylene glycols, with corresponding isocyanatosilanes. These are, in particular, methyldimethoxysilylmethyl isocyanate, methyldiethoxysilylmethyl isocyanate, and trimethoxysilylpropyl isocyanate. In this case —X— in formula (1) is —O—, and R⁵ is hydrogen.

Polyoxyalkylenes that contain polyethers as a polymer backbone possess a flexible and elastic structure not only at the terminal groups but also in the polymer spine. Compositions that exhibit very good elastic properties can be manufactured therewith. Polyethers are not only flexible in their framework, but also at the same time strong. For example, polyethers (in contrast to e.g. polyesters) are not attacked or decomposed by water and bacteria.

Polyethylene oxides and/or polypropylene oxides are therefore used with particular preference.

According to a preferred embodiment of the composition according to the present invention, the molecular weight Mₙ of the polymer backbone is between 4000 and 30,000 g/mol (daltons). Further particularly preferred molecular weight ranges are 5000 to 20,000 g/mol; 8000 to 19,000 g/mol are very particularly preferred.

These molecular weights are particularly advantageous because compositions having these molecular weights have viscosity values that enable easy processability.

Polyoxyalkylenes, in particular polyethylene oxides or polypropylene oxides, that exhibit a polydispersity PD of less than 2, preferably less than 1.5, in particular less than 1.3, are used with very particular preference.

The “molecular weight Mₙ” is understood as the number-average molecular weight of the polymer. This, like the weight-average molecular weight M_{w}, can be determined by gel permeation chromatography (GPC, also called SEC). This method is known to one skilled in the art. The polydispersity is derived from the average molecular weights M_{w} and Mₙ. It is calculated as PD=M_{w}/Mₙ.

Particularly advantageous viscoelastic properties can be achieved if polyoxyalkylene polymers that possess a narrow molecular weight distribution, and thus a low polydispersity, are used as polymer backbones. These can be manufactured, for example, by so-called double metal cyanide (DMC) catalysis. These polyoxyalkylene polymers are notable for a particularly narrow molecular weight distribution, a high average molecular weight, and a very small number of double bonds at the ends of the polymer chains. Such polyoxyalkylene polymers have a polydispersity PD (M_{w}/Mₙ) of at most 1.7. Particularly preferred organic backbones are, for example, polyethers having a polydispersity from approximately 1.01 to approximately 1.3, in particular approximately 1.05 to approximately 1.18, for example approximately 1.08 to approximately 1.11 or approximately 1.12 to approximately 1.14. In a preferred embodiment of the invention these polyethers have an average molecular weight (Mₙ) of approximately 4000 to approximately 30,000, in particular approximately 5000 to approximately 20,000. Polyethers having average molecular weights from approximately 6000 to approximately 20,000, in particular having average molecular weights from approximately 8000 to approximately 19,000, are particularly preferred.

Alternatively, the silane-terminated prepolymers to be used according to the present invention can be manufactured from the corresponding isocyanate-functional prepolymers and aminosilanes. In this case the aforesaid preferred polyoxyalkylene polyols are reacted with diisocyanates at a stoichiometric excess to yield NCO-terminated prepolymers that are then, in a subsequent reaction, reacted with the corresponding aminosilanes to produce the silane-terminated prepolymers.

A number of commercially available diisocyanates are suitable in principle as diisocyanates. Examples that may be recited are ethylene diisocyanate, 1,4-tetramethylene diisocyanate, 1,4-tetramethoxybutane diisocyanate, 1,6-hexamethylene diisocyanate (HDI), cyclobutane 1,3-diisocyanate, cyclohexane 1,3- and 1,4-diisocyanate, bis(2-isocyanatoethyl) fumarate, 1-isocyanato-3,3,5-trimethyl-5-isocyanatomethylcyclohexane (isophorone diisocyanate, IPDI), 2,4- and 2,6-hexahydrotoluylene diisocyanate, hexahydro-1,3- or -1,4-phenylene diisocyanate, benzidine diisocyanate, naphthalene 1,5-diisocyanate, 1,6-diisocyanato-2,2,4-trimethylhexane, 1,6-diisocyanato-2,4,4-trimethylhexane, xylylene diisocyanate (XDI), tetramethylxylylene diisocyanate (TMXDI), 1,3- and 1,4-phenylene diisocyanate, 2,4- or 2,6-toluylene diisocyanate (TDI), 2,4′-diphenylmethane diisocyanate, 2,2′-diphenylmethane diisocyanate, or 4,4′-diphenylmethane diisocyanate (MDI), as well as isomer mixtures thereof. Also suitable are partly or completely hydrogenated cycloalkyl derivatives of MDI, for example completely hydrogenated MDI (H12-MDI), alkyl-substituted diphenylmethane diisocyanates, for example mono-, di-, tri-, or tetraalkyldiphenylmethane diisocyanate as well as partially or completely hydrogenated cycloalkyl derivatives thereof, 4,4′-diisocyanatophenylperfluorethane, phthalic acid bisisocyanatoethyl ester, 1-chloromethylphenyl-2,4- or -2,6-diisocyanate, 1-bromomethylphenyl-2,4- or -2,6-diisocyanate, 3,3-bischloromethyl ether-4,4′-diphenyldiisocyanate, sulfur-containing diisocyanates such as those obtainable by reacting 2 mol diisocyanate with 1 mol thiodiglycol or dihydroxyhexylsulfide, the diisocyanates of the dimer fatty acids, or mixtures of two or more of the aforesaid diisocyanates.

The aminosilane can be selected in this context, for example, from 3-aminopropyltrimethoxysilane, 3-aminopropyltriethoxysilane (e.g. Dynasilan AMMO, Evonik company, or Geniosil GF 96, Wacker Co.), N-(n-butyl)-3-aminopropyltrimethoxysilane, N-cyclohexylaminomethylmethyldiethoxysilane, N-cyclohexylaminomethyltriethoxysilane, N-cyclohexylaminomethylmethyldimethoxysilane, N-cyclohexylaminomethyltrimethoxysilane, N-phenylaminomethyltrimethoxysilane (e.g. Geniosil XL 973, Wacker Co.), N-cyclohexyl-3-aminopropyltrimethoxysilane, 1-anilinomethyldimethoxymethylsilane (e.g. Geniosil XL972, Wacker Co).

The aforesaid silane-terminated prepolymers can be used to manufacture single-component moisture-hardening adhesive/sealant compositions according to the present invention. Adhesive/sealant compositions of this kind are indicated in particular for edge sealing or adhesive bonding of modules, since no components need to be mixed in this context, and curing by diffusion of water vapor out of the edge region ensures sufficiently rapid curing. For large-area bonding of non-porous substrates, however, one skilled in the art will select the two- or multi-component embodiment in order to ensure sufficient curing of the adhesive join.

In the two-component embodiment of the adhesive/sealant composition according to the present invention, component B by preference contains at least water as well as at least one thickening agent. Component B contains by preference 1 to 20 wt %, particularly preferably 3 to 15 wt % water, this quantitative indication referring to the total weight of component B. The water is preferably adsorbed onto inorganic thickening agents, or dissolved resp. swollen into organic thickening agents. Component B can furthermore contain an oligomer; this is by preference a polypropylene glycol, polyethylene glycol, or a copolymer of propylene oxide and ethylene oxide. Mixtures of different polyoxyalkylenes can also be used. The molecular weights of the polyoxyalkylene(s) are by preference between 1000 and 20,000, particularly preferably between 2000 and 12,000.

Water-soluble resp. water-swellable polymers or inorganic thickening agents are preferred as thickening agents for the preferred embodiment. Examples of organic natural thickening agents are agar-agar, carrageenan, tragacanth, gum arabic, alginates, pectins, polyoses, guar flour, starch, dextrins, gelatins, casein. Examples of entirely or partly synthetic organic thickening agents are carboxymethyl cellulose, cellulose ethers such as e.g. tylose, hydroxyethyl cellulose, hydroxypropyl cellulose, poly(meth)acrylic acid derivatives, polyvinyl ethers, polyvinyl alcohol, polyamides, polyimines. Examples of inorganic thickening agents resp. adsorption agents for water are polysilicic acids, highly dispersed, pyrogenic, hydrophilic silicic acids, clay minerals such as montmorillonite, kaolinite, or halloysite, as well as aluminum hydroxide, aluminum oxide hydrate, aluminum silicates, talc, quartz minerals, magnesium hydroxide, or the like.

Component B is by preference embodied so that component A is mixed with component B at a ratio from 1:1 to 200:1 parts by weight in order to ensure quick and complete curing. Particularly preferably, component A and component B are mixed at a ratio from 1:1 to 100:1 parts by weight, more preferably from 5:1 to 20:1.

Both component A and also, if applicable, component B can additionally contain fillers, plasticizers, aging protection agents, rheology adjuvants, and further adjuvants and additives.

All plasticizers usual for adhesives/sealants can be used as plasticizers, for example the various phthalic acid esters, arylsulfonic acid esters, alkyl and/or aryl phosphates, and the dialkyl esters of the aliphatic and aromatic dicarboxylic acids.

Suitable plasticizers are, among others, adipic acid esters, azelaic acid esters, benzoic acid esters, butyric acid esters, acetic acid esters, esters of higher fatty acids having approximately 8 to approximately 44 carbon atoms, esters of OH-group-carrying or epoxidized fatty acids, fatty acid esters, and fats, glycolic acid esters, phosphoric acid esters, phthalic acid esters of linear or branched alcohols containing 1 to 12 carbon atoms, propionic acid esters, sebacic acid esters, sulfonic acid esters (e.g. “Mesamoll,” alkylsulfonic acid phenyl ester, Bayer Co.), thiobutyric acid esters, trimellitic acid esters, citric acid esters, and esters based on nitrocellulose and polyvinyl acetate, as well as mixtures of two or more thereof. The asymmetrical esters of adipic acid monooctyl ester with 2-ethylhexanol (Edenol DOA, Cognis Deutschland GmbH, Düsseldorf), or also esters of abietic acid, are particularly suitable. Also suitable are low-molecular-weight hydrocarbon resins based on C₉ hydrocarbons, for example Novares L 100, Novares LA 300, Novares LC 10, Novares XK 096, or Novares XK 114 of the Rütgers company.

Suitable among the phthalic acid esters, for example, are dioctyl phthalate (DOP), dibutyl phthalate, diisononyl phthalate (DINP), diisoundecyl phthalate (DIUP), or butylbenzyl phthalate (BBP) or hydrogenated derivatives derived therefrom; among the adipates, dioctyl adipate (DOA), diisodecyl adipate, diisodecyl succinate, dibutyl sebacate, or butyl oleate.

All common coated or uncoated fillers and/or pigments can be used as fillers and/or pigments, although their water content should preferably be low. Examples of suitable fillers are limestone flour, natural ground chalks (calcium carbonates or calcium magnesium carbonates), precipitated chalks, talc, mica, clays, magnesium hydroxide or aluminum hydroxide, kaolins, or barite. Examples of suitable pigments are titanium dioxide, iron oxides, or carbon black.

Aging protection agents or “stabilizers” are to be understood for purposes of this invention as antioxidants, UV stabilizers, or hydrolysis stabilizers. Examples thereof are the commercially usual sterically hindered phenols and/or thioethers and/or substituted benzotriazoles, for example Tinuvin 327 or 328 (Ciba Specialty Chemicals), and/or amines of the hindered amine light stabilizer (HALS) type, for example Tinuvin 770 (Ciba Specialty Chemicals). It may be preferred in the context of the present invention if a UV stabilizer that carries a silyl group, and that is incorporated into the final product upon crosslinking or curing, is used. The products Lowilite 75, Lowilite 77 (Great Lakes company, USA) are particularly suitable for this purpose. Benzotriazoles, benzophenones, benzoates, cyanoacrylates, acrylates, sterically hindered phenols, phosphorus, and/or sulfur can also be added. The preparation according to the present invention can contain up to approximately 2 wt %, by preference approx. 1 wt % stabilizers. In addition, the preparation according to the present invention can further contain up to approximately 7 wt %, in particular up to approx. 5 wt % antioxidants.

Hydrogenated castor oil (e.g. Rilanit, Cognis Deutschland GmbH, Düsseldorf), fatty acid amides, or swellable plastics such as PVC can be used, for example, as rheological adjuvants.

The compositions according to the present invention, in this case in particular component A, by preference contain adhesion promoters and/or reactive diluents, in the form of low-molecular-weight organofunctional silanes, as further additives. Particularly preferred in this context are 3-glycidoxypropyltrialkoxysilane—in particular 3-glycidoxypropyltrimethoxysilane (Dynasylan GLYMO, Evonik company) or 3-glycidoxypropyltriethoxysilane (Dynasylan GLYEO, Evonik), 3-acryloxypropyltrialkoxysilane, 3-aminopropyltrialkoxysilane, vinyltrialkoxysilane, phenylaminopropyltrialkoxysilane, aminoalkyltrialkoxydisilane, N(2-aminoethyl)-3-aminopropyltrialkoxysilane, 3-glycidoxypropylalkyldialkoxysilane, 3-acryloxypropylalkyldialkoxysilane, 3-aminopropylalkyldialkoxysilane, vinylalkyldialkoxysilane, phenylaminopropylalkyldialkoxysilane, aminoalkylalkyldialkoxydisilane, N(2-aminoethyl)-3-aminopropylalkyldialkoxysilane, isobutylmethoxysilane, bis(trimethoxysilylpropyl)amine (Dynasylan 1124, Evonik), N-(trimethoxysilylmethyl)-O-methylcarbamate, N-dimethoxy(methy)silylmethyl-O-methylcarbamate, (N-phenylaminomethyl)trimethoxysilane, (N-cyclohexylaminomethyltriethoxysilane, (N-cyclohexylaminomethyl)methyldiethoxysilane (N-phenylaminomethyl)methyldimethoxysilane, (N-phenylaminomethyl)trimethoxysilane, partial hydrolysates of the aforesaid silanes, or mixtures of the aforesaid silanes and/or partial hydrolysates.

Component B can also contain diluents resp. solvents as further additives. Examples of suitable diluents are ethylene glycol, diethylene glycol, neopentyl glycol, hexanediol, butanediol, propylene glycol, glycerol, triethylene glycol, tetraethylene glycol, polyethylene glycol, or monomethyl ethers thereof, as well as mixtures of the aforesaid compounds, or phosphate plasticizers (e.g. TEP, TOF).

Manufacture of the preparation according to the present invention is accomplished in accordance with known methods, by intimate mixing of the constituents in suitable dispersing equipment, e.g. high-speed mixers, kneaders, planetary mixers, planetary dissolvers, internal mixers, so-called “Banbury” mixers, double-screw extruders, and similar mixing equipment known to one skilled in the art; in the case of the two-component embodiments, component B must of course be manufactured and packaged separately.

The compositions according to the present invention can typically contain:
Component A
Silane-terminated prepolymer: 15.0 to 70.0 wt %, by preference 20 to 50 wt %,
Plasticizer: 0 to 20 wt %,
Fillers: 0 to 50 wt %,
Rheology adjuvants: 0 to 4 wt %,
Pigments: 0 to 10 wt %,
Stabilizers: 0 to 5 wt %,
Adhesion promoters/reactive diluents: 0.1 to 5 wt %,
the sum total of the constituents of component A adding up to 100 wt %.

In the case of the two-component embodiment:
Component B:
Water: 1.0 to 20.0 wt %,
Oligomer: 20.0 to 50.0 wt %,
Fillers: 10.0 to 50.0 wt %,
Diluent: 0 to 5.0 wt %,
Thickening agent: 0.1 to 5.0 wt %,
the sum total of the constituents of component B adding up to 100 wt %.

Depending on the specific embodiment, components A and B are to be mixed before utilization at a ratio from 1:1 to 200:1, by preference 1:1 to 100:1.

The invention will be further explained with reference to the Examples that follow. All quantitative indications are in percent by weight unless otherwise indicated.

### EXAMPLES

### Examples 1 and 2

Component A of a single- resp. two-component adhesive/sealant was manufactured in a high-speed mixer on the basis of an α-silane-terminated polypropylene glycol having N-(dimethoxy(methyl)silylmethyl)carbamate terminal groups (30,000 mPa·s at 25° C., per DIN 51562), with moisture excluded:

TABLE 1

Example

| | 1 | 2 |
|---|---|---|
| Alpha-silane polymer | 29.61 | 29.16 |
| DINP | 9.35 | 9.21 |
| Tinuvin solution | 1.25 | 1.23 |
| Rilanit | 2.08 | 2.05 |
| Titanium dioxide, dried | 6.23 | 6.14 |
| Chalk, Omya BLH, dried | 48.83 | 48.08 |
| Tinuvin 328 | 0.05 | 0.05 |
| Dynasylan GLYMO | 0.52 | 2.05 |
| Dynasylan 1124 | 2.08 | 2.05 |
| TOTAL | 100.00 | 100.00 |

### Example 3

A hardener component B was manufactured by mixing the following constituents:

TABLE 2

| | |
|---|---|
| Polypropylene glycol 6300 (Acclaim, Bayer co.) | 48.64 |
| Calcium carbonate | 38.00 |
| Monoethylene glycol, distilled | 3.00 |
| Tylose MH | 0.36 |
| Water | 10.00 |
| TOTAL | 100.00 |

### Examples 4 to 7

In Examples 4 and 6 below, components A of Examples 1 and 2 were tested in single-component form, and in Examples 5 and 7 together with component B of Example 3, for compatibility and hardening behavior with solar module substrates and metals (aluminum, 99.5 purity).

TABLE 3

| Example | 4 | 5 | 6 | 7 | MS sealant | MS sealant |
|---|---|---|---|---|---|---|
| Embodiment (1-C or 2-C) | 1-C | 2-C | 1-C | 2-C | 1-C | 2-C |
| Open time (min) | — | 15-20 | — | ca. 15 | — | 30-40 |
| Shore A | | | | | | |
| 1 day SC | 33 | 47 | 34 | 46 | 20 | 18 |
| 7 days SC | 53 | 49 | 54 | 50 | 30 | 28 |
| Aged: 7 days SC | | | | | | |
| Adhesion to Uni-Solar | 1 | 1 | 1 | 1 | 1 | 1 |
| module (after corona | | | | | | |
| pretreatment | | | | | | |
| Adhesion to Al 99.5 | 1 | 1 | 1 | 1 | 1 | 1 |
| Adhesion to | 1 | 1 | 1 | 1 | 1 | 1 |
| Evalon (EVA sheet) | | | | | | |
| Compatibility with film = | no visible | no visible | no visible | no visible | no visible | no visible |
| adhesion film/metal part | attack | attack | attack | attack | attack | attack |
| of film | on film | on film | on film | on film | on film | on film |
| Aged: 7 days SC + 21 | | | | | | |
| days 80° C. | | | | | | |
| Adhesion to Uni-Solar | 1 | 1 | 1 | 1 | 4 | 4 |
| module (after corona | | | | | | |
| pretreatment | | | | | | |
| Adhesion to Al 99.5 | 1 | 1 | 1 | 1 | 1 | 1 |
| Adhesion of adhesive to | 1 | 1 | 1 | 1 | 1 | 1 |
| Evalon | | | | | | |
| Compatibility with Uni- | yes | yes | yes | yes | delamination | delamination |
| Solar module | | | | | | |

In Table 3:
1-C = Hardens by atmospheric moisture only
2-C = Hardens with component B
SC = Standard climate (50% RH/23° C.)
Adhesion: 1 = 100% cohesive break (OK); 4 = >80% adhesive break (not OK)

Table 4 below summarizes the strength properties of the adhesives according to the present invention in accordance with Examples 5 and 7 (10:1 mixing ratio of component A to B) before and after high-temperature aging.

For this, the aforementioned mixtures were produced and were processed into flat plates having a layer thickness of 2 mm. After 7 days of aging (23° C., 50% relative humidity), specimens (S2 test specimens) were punched out of these and the mechanical data (E-moduli at 10, 25, 50, and 100% elongation, elongation at fracture, and breaking strength) were determined on the basis of DIN EN 27389 and DIN EN 28339.

TABLE 4

Example

| | 5 | 7 |
|---|---|---|
| Open time (min) | 15-20 | 15-20 |
| Shore A | | |
| after 1 d SC | 45 | 38 |
| after 7 d SC | 52 | 50 |
| Mechanical data, S2 specimen | | |
| 10% modulus (N/mm²) 1 d SC | 0.30 | 0.22 |
| 25% modulus (N/mm²) 1 d SC | 0.58 | 0.41 |
| 50% modulus (N/mm²) 1 d SC | 0.82 | 0.63 |
| 100% modulus (N/mm²) 1 d SC | 0.87 | 0.72 |
| Breaking strength (N/mm²) 1 d | 0.88 | 0.80 |
| SC | | |
| Elongation (%) 1 d SC | 97 | 163 |
| Mechanical data, S2 specimen | | |
| 10% modulus (N/mm²) 7 d SC | 0.35 | 0.29 |
| 25% modulus (N/mm²) 7 d SC | 0.67 | 0.57 |
| 50% modulus (N/mm²) 7 d SC | 0.94 | 0.83 |
| 100% modulus (N/mm²) 7 d SC | 1.03 | 0.93 |
| Breaking strength (N/mm²) 7 d | 1.03 | 0.97 |
| SC | | |
| Elongation (%) 7 d SC | 99 | 120 |

The outstanding properties of the adhesives/sealants according to the present invention in the context of adhesive bonding of substrates that are used in BIPV applications are evident from the test results summarized in Tables 3 and 4.

In a comparative investigation, an adhesive/sealant of the existing art (MS sealant) was tested. The sealant is based on y-silane-terminated polypropylene glycols having dimethoxy(methyl)silyl terminal groups, and comprises 0.3 wt % of a usual tin catalyst. The adhesive bond exhibited usable initial values, but complete delamination of the adhesive from the polymer rear film of the solar module was observed after one week of high-temperature aging at 80° C. Such adhesives/sealants of the existing art are thus unsuitable for the installation of BIPV systems.

What is claimed is:

1. A method of bonding a substrate of a photovoltaic module to a second substrate comprising:
providing a single- or multi-component adhesive/sealant composition containing at least one silane-terminated prepolymer, wherein the heavy-metal content of the adhesive/sealant composition, based on the total weight of the adhesive/sealant composition and calculated as metal, is equal to a maximum of 0.01 wt %; and the terminal groups of the silane-terminated prepolymer are selected from methyldialkoxysilylpropyl, trialkoxysilylpropyl, methyldialkoxysilylmethyl, trialkoxysilylmethyl, or mixtures thereof,
providing the photovoltaic module and the second substrate;
disposing the composition over a portion of at least one of the photovoltaic module and the second substrate;
placing the disposed composition on the other of the photovoltaic module and the second substrate; and
curing the disposed adhesive composition to bond the substrates.

2. The method of claim 1, wherein the composition is embodied with two components, made up of a component A containing at least one silane-terminated prepolymer and a component B containing water as well as at least one thickening agent.

3. The method of claim 1, wherein the at least one silane-terminated prepolymer is a silane-terminated polyoxyalkylene having N-(dimethoxy(methyl)silylmethyl)carbamate terminal groups.

4. The method of claim 1, wherein the silane-terminated prepolymer has a molecular weight (Mₙ) between 1000 and 50,000, by preference between 4000 and 20,000.

5. The method of claim 1, wherein the composition is made up of a component A containing at least one silane-terminated prepolymer and a component B containing water as well as at least one thickening agent, wherein component B is consisting of a mixture of at least one oligomer, plasticizer(s), water, thickening agents, and optionally further adjuvants.

6. The method of claim 1, wherein the composition is made up of a component A containing at least one silane-terminated prepolymer and a component B containing water as well as at least one thickening agent, wherein the thickening agent is selected from at least one of polysilicic acid, highly dispersed pyrogenic silicic acid, aluminum hydroxide, aluminum oxide hydrate, talc, quartz minerals, magnesium hydroxide, and clay minerals.

7. The method of claim 1, wherein the composition is made up of a component A containing at least one silane-terminated prepolymer and a component B containing water as well as at least one thickening agent, wherein the thickening agent comprises natural organic thickening agents and entirely or partly synthetic organic thickening agents.

8. The method of claim 1, wherein the composition is made up of a component A containing at least one silane-terminated prepolymer and a component B consisting of a mixture of at least one oligomer, at least one plasticizer, water, at least one thickening agent, and optionally one or more further adjuvants, wherein the oligomer of component B is a polyoxyalkylene or a mixture of various polyoxyalkylenes, by preference a polypropylene glycol, having a molecular weight between 1000 and 20,000, preferably between 2000 and 12,000, or a mixture of polyoxyalkylenes of various molecular weights.

9. The method of claim 1, wherein the adhesive/sealant composition further contains at least one low-molecular-weight organofunctional silane that is selected from 3-glycidoxypropyltrialkoxysilane, 3-acryloxypropyltrialkoxysilane, 3-aminopropyltrialkoxysilane, vinyltrialkoxysilane, phenylaminopropyltrialkoxysilane, aminoalkyltrialkoxydisilane, N(2-aminoethyl)-3-aminopropyltrialkoxysilane, 3-glycidoxypropylalkyldialkoxysilane, 3-acryloxypropylalkyldialkoxysilane, 3-aminopropylalkyldialkoxysilane, vinylalkyldialkoxysilane, phenylaminopropylalkyldialkoxysilane, aminoalkylalkyldialkoxydisilane, N(2-aminoethyl)-3-aminopropylalkyl-dialkoxysilane, isobutylmethoxysilane, bis(trimethoxysilylpropyl)amine, N-(trimethoxysilylmethyl)-O-methylcarbamate, N-dimethoxy(methyl)silylmethyl-O-methylcarbamate, (N-phenylaminomethyl)trimethoxysilane, (N-cyclohexylaminomethyl)triethoxysilane, (N-cyclohexylaminomethyl)methyldiethoxysilane, (N-phenylaminomethyl)methyldimethoxysilane, (N-phenylaminomethyl) trimethoxysilane, partial hydrolysates of the aforesaid silanes, or mixtures of the aforesaid silanes and/or partial hydrolysates.

10. The method of claim 1, wherein the composition is embodied with two components, made up of a component A containing at least one silane-terminated prepolymer and a component B containing 1 to 20 wt % water, based on the total weight of component B as well as at least one thickening agent.

11. The method of claim 1, wherein the composition is embodied with two components, made up of a component A containing at least one silane-terminated prepolymer and a component B containing water as well as at least one thickening agent, wherein the weight ratio of components A and B is equal to 1:1 to 200:1.

12. The method of claim 1, wherein the second substrate is a portion of a photovoltaic module.

13. The method of claim 1, wherein the second substrate is a portion of a roof surface.

14. The method of claim 1, wherein the photovoltaic module substrate is one layer of a solar film and the second substrate is another layer of the solar film.

15. A photovoltaic module portion bonded to a surface by cured reaction products of a single- or multi-component adhesive/sealant composition containing at least one silane-terminated prepolymer, wherein the heavy-metal content of the adhesive/sealant composition, based in each case on the total weight of the adhesive/sealant composition and calculated as metal, is equal to a maximum of 0.01 wt %; and the terminal groups of the silane-terminated prepolymer are selected from methyldialkoxysilylpropyl, trialkoxysilylpropyl, methyldialkoxysilylmethyl, trialkoxysilylmethyl, or mixtures thereof.

16. The photovoltaic module of claim 15 wherein the surface is a portion of a roof surface.

17. The photovoltaic module of claim 15 wherein the surface is a portion of a solar film.
